(19) United States
(12) Patent Application Publication
(10) Pub. No.: US 2013/0087201 A1
(43) Pub. Date: Apr. 11, 2013

(54) PRODUCTION OF SOLAR CELL MODULES

(71) Applicants: Peter Battenhausen, Brachttal-Udenhain (DE); Ernst Becker, Bensheim (DE); Klaus Schultes, Wiesbaden (DE); Sven Strohkark, Darmstadt (DE)

(72) Inventors: Peter Battenhausen, Brachttal-Udenhain (DE); Ernst Becker, Bensheim (DE); Klaus Schultes, Wiesbaden (DE); Sven Strohkark, Darmstadt (DE)

(73) Assignee: Evonik Roehm GmbH, Darmstadt (DE)

(21) Appl. No.: 13/805,351

(22) PCT Filed: Jun. 1, 2011
(86) PCT No.: PCT/EP11/59002

§ 371 Date: Dec. 19, 2012

(30) Foreign Application Priority Data
Jun. 25, 2010 (JP) 10 2010 030 508.1

(51) Int. Cl. H01L 31/0203; H01L 31/18

(52) U.S. Cl. CPC H01L 31/0203; H01L 31/18
USPC 136/259; 438/64

(57) ABSTRACT

The invention relates to the use of a) at least one (poly)alkyl(meth)acrylate and b) at least one compound according to formula (I), wherein the radicals R¹ and R² independently represent an alkyl or cycloalkyl radical having 1 to 20 carbon atoms, for producing solar cell modules, in particular for producing light concentrators for solar cell modules.

The present invention relates to the production of solar cell modules and the corresponding solar cell modules.

### PRIOR ART

A solar cell or photovoltaic cell is an electrical component, which converts the radiant energy contained in light, in particular in sunlight, directly into electrical energy. The physical basis of this conversion is the photovoltaic effect, which is a special case of the internal photoelectric effect.

FIG. 3 is a schematic cross-section showing the basic structure of a solar cell module. In FIG. 3, 501 denotes a photovoltaic cell, 502a reinforcing agent, 503a plate and 504a rear wall. Sunlight impinges on the light-sensitive surface of the photovoltaic cell 501, having passed through the plate 503 and the reinforcing agent 502, and is converted into electrical energy. The current produced is delivered by output terminals (not shown).

The photovoltaic cell cannot withstand extreme external conditions, because it corrodes easily and is very fragile. It must therefore be covered and protected by a suitable material. In most cases this is achieved by inserting and laminating the photovoltaic cell using a suitable reinforcing agent between a weatherproof transparent plate, e.g. a glass plate, and a rear wall with excellent moisture resistance and high electrical resistance.

Polyvinylbutyral and ethylene-vinyl acetate copolymers (EVA) are often used as reinforcing agents for solar cells. In particular, crosslinkable EVA compositions display excellent properties, such as good heat resistance, high resistance to weathering, high transparency and good cost-effectiveness.

The solar cell module must be extremely durable, because it will be used outside for a long time. Therefore the reinforcing agent must possess, among other things, excellent resistance to weathering and high thermostability. However, light-induced and/or heat-induced degradation of the reinforcing agent and consequent yellowing of the reinforcing agent and/or peeling of the photovoltaic cell are often observed, when the module is used outside for a long time, e.g. ten years. The yellowing of the reinforcing agent leads to a decrease in the usable fraction of the incident light and therefore lower electrical performance. Furthermore, peeling of the photovoltaic cell permits penetration of moisture, which can lead to corrosion of the photovoltaic cell itself or of metallic parts in the solar cell module and may also result in impairment of the performance of the solar cell module.

Although the EVAs usually employed are good reinforcing agents in themselves, they are gradually degraded by hydrolysis and/or pyrolysis. With time, heat or moisture causes acetic acid to be released. This leads to yellowing of the reinforcing agent, to a decrease in mechanical strength and to a decrease in adhesiveness of the reinforcing agent. In addition, the acetic acid released acts as a catalyst and causes additional acceleration of degradation. Furthermore, there is the problem that the photovoltaic cell and/or other metal parts in the solar cell module are corroded by the acetic acid.

To solve these problems, European patent application EP 1 065 731 A2 proposes the use of a solar cell module that comprises a photovoltaic cell and a polymeric reinforcing agent, and said polymeric reinforcing agent is to contain an ethylene-acrylate-acrylic acid terpolymer, an ethylene-acrylate-maleic acid anhydride terpolymer, an ethylene-methacrylic acid ester-acrylic acid ester terpolymer, an ethylene-acrylic acid ester-methacrylic acid terpolymer, an ethylene-methacrylic acid ester-methacrylic acid terpolymer and/or an ethylene-methacrylic acid ester-maleic acid anhydride terpolymer. However, both the resistance to weathering and the efficiency of such solar cell modules are limited.

Improvement of the resistance to weathering of acrylic moulding compounds by using suitable UV absorbers is also known from the prior art.

Thus, DE 103 11 641 A1 describes tanning aids that comprise a polymethyl methacrylate moulding, which contains 0.005 wt. % to 0.1 wt. % of a UV stabilizer according to formula (I)

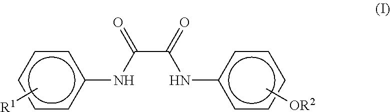

in which the residues R¹ and R² represent independently an alkyl or cycloalkyl residue with 1 to 20 carbon atoms.

However, that publication does not give any information on the use of the mouldings for the production of solar cell modules.

DE 38 38 480 A1 discloses methyl methacrylate polymers and copolymers, which contain
a) an oxalic acid anilide or 2,2,6,6-tetramethylpiperidine compound as stabilizer against damage by light and
b) a fire-retardant organic phosphorus compound.

However, that publication does not give any information on the use of the composition for the production of solar cell modules.

JP 2005-298748 A discloses mouldings of a methacrylic resin, which preferably contain 100 parts by weight of methacrylic resin, comprising 60-100 wt. % of methyl methacrylate units and 0-40 wt. % of other copolymerizable vinyl monomer units, and 0.005-0.15 wt. % of 2-(2-hydroxy-4-n-octyloxyphenyl)-4,6-bis(2,4-dimethylphenyl)-1,3,5-triazine and/or 2-hydroxy-4-octyloxybenzophenone. The mouldings are said to have a definite barrier to UV rays and to display a transparency of at most 20% at 340 nm and a transparency of at least 70% at 380 nm, measured on mouldings with a thickness in the range from 0.5 to 5 mm.

The mouldings are to be used in particular as lighting fixture coverings. However, that publication does not give any information on the use of the mouldings for the production of solar cell modules.

### SUMMARY OF THE INVENTION

An object of the present invention is therefore to demonstrate possible ways of reducing the drop in performance of a solar cell in long-term use outdoors, in particular at high temperature and/or high humidity. For this purpose, in particular ways were sought for achieving excellent resistance to weathering, maximum possible thermostability and maximum transparency together with minimum water absorption.

Especially for multijunction solar cells (also called tandem solar cells or stacked solar cells), materials should be made available that offer optimum protection of the solar modules and make optimum efficiency possible.

Furthermore, minimal release of corrosive substances, in particular acids, and maximum adhesion to the various basic components of a solar cell module were also required.

These and other problems that are not concretely stated, but are obvious from the context of the discussion in the introduction, are solved by using a moulding compound with all the features of Claim 1 of the present patent. The subclaims that refer back to Claim 1 describe particularly desirable variants of the invention. Furthermore, protection is also sought for the corresponding solar cell modules.

By using
a) at least one (poly)alkyl(meth)acrylate and
b) at least one compound according to formula (I)

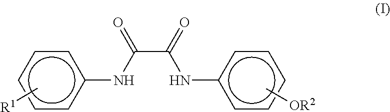

in which the residues R¹ and R² represent independently an alkyl or cycloalkyl residue with 1 to 20 carbon atoms,
   for the production of solar cell modules, and by ensuring that the solar cell has at least one component comprising a polyalkyl(meth)acrylate, with the concentration of the compound according to formula (I) in this component being in the range defined below

$${C}_{UV - absorber} = \frac{0.1 [ wt . \% \times mm ]}{{d}_{moulding} [ mm ]} to \frac{0.6 [ wt . \% \times mm ]}{{d}_{moulding} [ mm ]}$$

it is possible, in a manner not immediately foreseeable, to provide optimum prevention of a drop in performance of a solar cell, in particular a multijunction solar cell, during long-term use outdoors, in particular at high temperature and/or high humidity. In particular, excellent resistance to weathering, very high heat resistance and very high transparency plus generally low water absorption are achieved. Moreover, it ensures that the spectral region of sunlight that is usable by the solar cell, in particular by multijunction solar cells, is not absorbed, but there is optimum absorption of the harmful UV region.

Furthermore, even with long-term use outdoors, no corrosive substances are released, and very strong adhesion on the various basic components of a solar cell module is achieved.

The solution presented here therefore provides the most efficient use of “usable” light in the visible wavelength region. At the same time, other wavelength regions, in particular in the UV region, which cannot be used for production of current, are absorbed extremely effectively. This absorption increases the resistance to weathering of the solar cell modules. Furthermore, the absorption prevents deleterious heating of the light collectors, without having to use cooling elements for this purpose, and the life of the solar cell modules is prolonged. At the same time, the solar cell can display its full spectrum of action.

In particular, the following advantages are offered by the procedure according to the invention:

It provides access to a solar cell module with excellent resistance to weathering, heat resistance and moisture resistance. No peeling occurs, even if the module is exposed to outdoor conditions for a long time. Furthermore, the resistance to weathering is improved, as no acid is released, even at high temperatures and high humidity. As there is no corrosion of the photovoltaic cell by acid, stable durable performance of the solar cell is maintained over a long period.

Furthermore, materials are used that have outstanding resistance to weathering, thermostability and moisture resistance and that have excellent transparency, permitting very good solar cell modules to be produced.

### DESCRIPTION OF THE DRAWINGS

FIG. 1 is a schematic cross-section of a preferred solar cell module according to the present invention.

FIGS. 2a and 2b are schematic cross-sections, which show the basic structure of a photovoltaic cell that is preferably used in the solar cell module according to FIG. 1, and a top view of the light-sensitive area of the photovoltaic cell.

FIG. 3 is a schematic cross-section of a conventional solar cell.

FIG. 4: Transmission spectrum of comparative example 1

FIG. 5: Transmission spectrum of comparative example 2

FIG. 6: Comparison of the transmission spectra of examples 1 to 5

FIG. 7: Long-term weathering test of example 6 based on the respective transmission spectra

FIG. 8: Sensitivity of a multijunction solar cell (CDO-100 Concentrator Photovoltaik Cell, from the company Spectrolab Inc. (USA)) as a function of the wavelength of the incident light in the wavelength range from 250 to 450 nm

FIG. 9: Sensitivity of a multijunction solar cell in relation to the wavelength of the incident light in the wavelength range from 330 to 1730 nm

### REFERENCE SYMBOLS

FIG. 1
101 photovoltaic cell
102 reinforcing agent
103 plate
104 reinforcing agent
105 rear wall

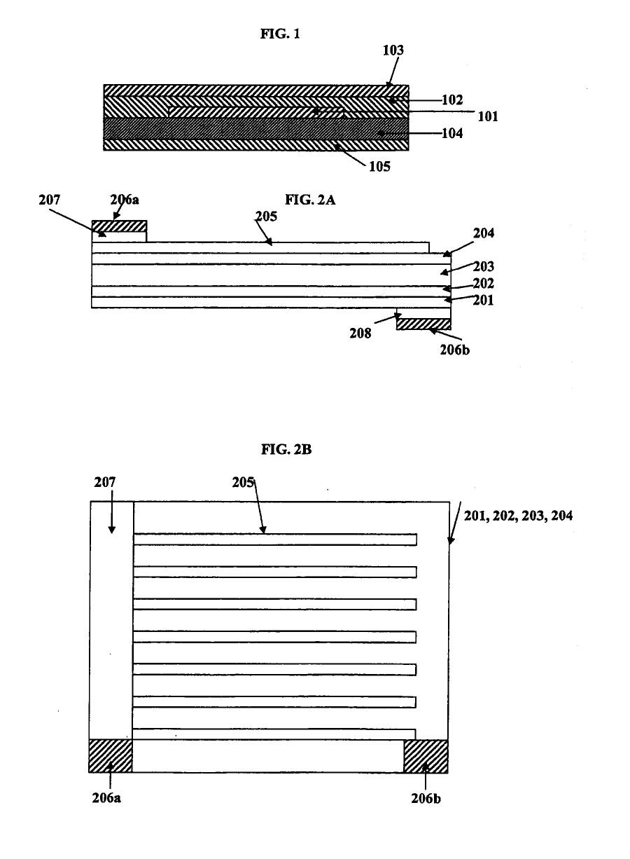

FIG. 2a
201 conductive substrate
202 reflective layer
203 photoactive semiconductor layer
204 transparent conductive layer
205 collector electrode
206a connector
206b connector
207 conductive, adhesive paste
208 conductive paste or tin solder

FIG. 2b
201 conductive substrate
202 reflective layer
203 photoactive semiconductor layer
204 transparent conductive layer
205 collector electrode
206a connector
206b connector
207 conductive, adhesive paste

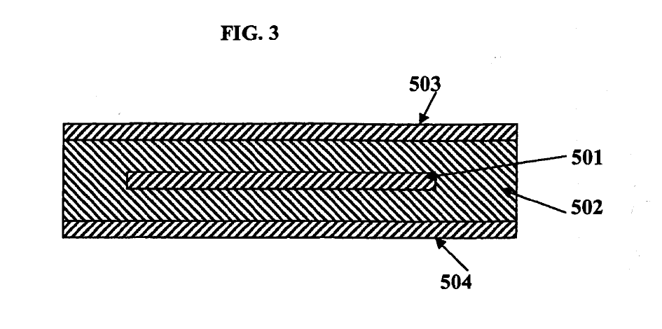

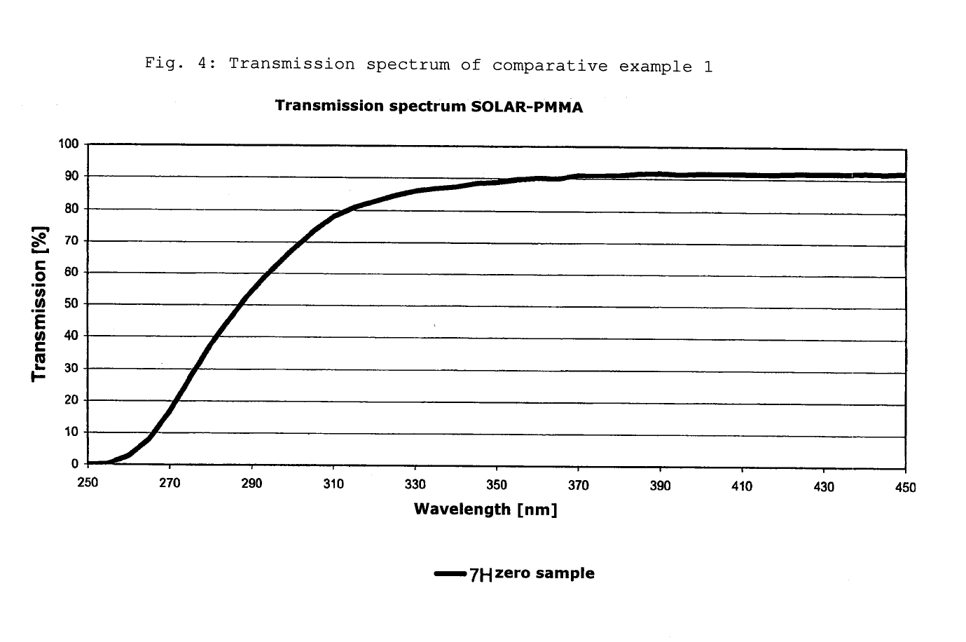

FIG. 3
501 photovoltaic cell
502 reinforcing agent
503 plate
504 rear wall

### DETAILED DESCRIPTION OF THE INVENTION

Within the scope of the present invention
a) at least one (poly)alkyl(meth)acrylate and
b) at least one compound according to formula (I)

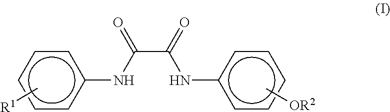

in which the residues R¹ and R² represent independently an alkyl or cycloalkyl residue with 1 to 20 carbon atoms,
   are used for the production of solar cell modules, ensuring that the solar cell has at least one component comprising a polyalkyl(meth)acrylate and that the concentration of the compound according to formula (I) in this component/these components is in the range defined below:

$${C}_{UV - absorber} = \frac{0.1 [ wt . \% \times mm ]}{{d}_{moulding} [ mm ]} to \frac{0.6 [ wt . \% \times mm ]}{{d}_{moulding} [ mm ]}$$

“(Poly)alkyl(meth)acrylate” stands for “polyalkyl(meth)acrylate” respectively for “alkyl(meth)acrylate” respectively for mixtures of both, e.g. in form of a syrup which may be used for cast processes.

“Component comprising a polyalkyl(meth)acrylate and a compound according to formula (I)” means, within the scope of the present invention, a component of a solar cell, e.g. a layer or a plate or a two- or three-dimensionally formed body, e.g. made of a reinforcing agent, which contributes to shielding of the solar modules against external harmful effects and contains both a polyalkyl(meth)acrylate and a compound according to formula (I). A solar cell according to the invention can contain several such elements, which may be constructed differently.

Preferably the concentration of the UV absorber (compound according to formula (I)) is in the range from

$${C}_{UV - absorber} = \frac{0.15 [ wt . \% \times mm ]}{{d}_{moulding} [ mm ]} to \frac{0.45 [ wt . \% \times mm ]}{{d}_{moulding} [ mm ]}$$

quite especially preferably in the range from

$${C}_{UV - absorber} = \frac{0.15 [ wt . \% \times mm ]}{{d}_{moulding} [ mm ]} to \frac{0.4 [ wt . \% \times mm ]}{{d}_{moulding} [ mm ]}$$

and most preferably in the range from

$${C}_{UV - absorber} = \frac{0.15 [ wt . \% \times mm ]}{{d}_{moulding} [ mm ]} to \frac{0.3 [ wt . \% \times mm ]}{{d}_{moulding} [ mm ]}$$

The aforementioned limits and units are explained as follows:

Transmission spectra (see examples) were measured on a 3 mm thick Plexiglas® plate with various concentrations of the UV absorbers used according to the invention (compound according to formula (I)). The concentrations of UV absorbers are determined, as shown below with an example of calculation with a UV absorber content of 0.06 wt. %:

$${C}_{UV - absorber} = \frac{3 [ mm ]}{{d}_{moulding} [ mm ]} 0.06 [ wt . \% ] = \frac{0.18 [ wt . \% \times mm ]}{{d}_{moulding} [ mm ]}$$

where:
C_{UV absorber}: denotes the concentration of the UV absorber compound according to formula (I) in the moulding compound or the casting monomer mixture or the component or layer of the solar cell, which contains the components a) and b)
d_{moulding}: denotes the thickness of the moulding

The factor in the numerator of the above equation therefore always refers to a 3 mm thick component (thick layer or plate). Taking into account the real thickness in the denominator of the above equations ensures that for components with different thicknesses, regardless of the real thickness, the appropriate action of the UV absorber is ensured.

The components a) and b) can be used together in a composition, e.g. as a mixture in a moulding compound or in a casting monomer mixture, for production of a component, e.g. a moulding, of the solar cell module. However, it is also possible for each to be used separately for the production of various individual elements of a solar cell module provided at least one element comprising both components a) and b) at the aforementioned concentration, is present in the solar cell.

The (poly)alkyl(meth)acrylate can be used alone or mixed with several different (poly)alkyl(meth)acrylates. Moreover, the polyalkyl(meth)acrylate can also be in the form of a copolymer.

Within the scope of the present invention, homo- and copolymers of C₁-C₁₈ alkyl(meth)acrylates, preferably of C₁-C₁₀ alkyl(meth)acrylates, in particular of C₁-C₄ alkyl(meth)acrylate polymers, which can optionally also contain various monomer units thereof, are especially preferred.

The notation (meth)acrylate used here denotes both methacrylate, e.g. methyl methacrylate, ethyl methacrylate etc., and acrylate, e.g. methyl acrylate, ethyl acrylate etc., and mixtures of both monomers.

The use of copolymers, which contain 70 wt. % to 99 wt. %, in particular 70 wt. % to 90 wt. %, of C₁-C₁₀ alkyl methacrylates, has proved quite especially useful. Preferred C₁-C₁₀ alkyl methacrylates comprise methyl methacrylate, ethyl methacrylate, propyl methacrylate, isopropyl methacrylate, n-butyl methacrylate, isobutyl methacrylate, tert.-butyl methacrylate, pentyl methacrylate, hexyl methacrylate, heptyl methacrylate, octyl methacrylate, isooctyl methacrylate and ethylhexyl methacrylate, nonyl methacrylate, decyl methacrylate and cycloalkyl methacrylates, for example cyclohexyl methacrylate, isobornyl methacrylate or ethylcyclohexyl methacrylate.

Quite especially preferred copolymers comprise 80 wt. % to 99 wt. % of methyl methacrylate (MMA) units and 1 wt. % to 20 wt. %, preferably 1 wt. % to 5 wt. %, of C₁-C₁₀ alkyl acrylate units, in particular methyl acrylate, ethyl acrylate and/or butyl acrylate units. The use of the polymethyl methacrylate PLEXIGLAS® 7N that is available from the company Röhm GmbH has proved quite especially useful in this connection.

The polyalkyl(meth)acrylate can be produced by methods of polymerization that are known per se, with methods of radical polymerization, in particular bulk, solution, suspension and emulsion polymerization methods being especially preferred. Initiators that are especially suitable for these purposes comprise in particular azo compounds, such as 2,2′-azobis(isobutyronitrile) or 2,2′-azobis(2,4-dimethylvaleronitrile), redox systems, for example the combination of tertiary amines with peroxides or sodium disulphite and potassium, sodium or ammonium persulphates or preferably peroxides (see for example H. Rauch-Puntigam, Th. Völker, “Acrylic and methacrylic compounds”, Springer, Heidelberg, 1967 or Kirk-Othmer, Encyclopedia of Chemical Technology, Vol. 1, pages 386ff, J. Wiley, New York, 1978). Examples of particularly suitable peroxide polymerization initiators are dilauroyl peroxide, tert.-butyl peroctoate, tert.-butyl perisononanoate, dicyclohexyl peroxydicarbonate, dibenzoyl peroxide and 2,2-bis(tert.-butylperoxy)-butane. The polymerization can also preferably be carried out with a mixture of various polymerization initiators with different half-lives, for example dilauroyl peroxide and 2,2-bis(tert.-butylperoxy)-butane, in order to maintain a constant radical flux during polymerization and at different polymerization temperatures. The amounts of polymerization initiator used are generally from 0.01 wt. % to 2 wt. % relative to the monomer mixture.

Polymerization can be carried out as a continuous process or as a batch process. After polymerization, the polymer is obtained by conventional isolation and separation steps, e.g. filtration, coagulation and spray drying.

The chains lengths of the polymerizates or copolymerizates can be adjusted by polymerization of the monomer or monomer mixture in the presence of molecular-weight regulators, such as in particular the mercaptans that are known for this, for example n-butylmercaptan, n-dodecylmercaptan, 2-mercaptoethanol or 2-ethylhexylthioglycolate, pentaerythritol tetrathioglycolate; the molecular-weight regulators generally being used in amounts from 0.05 wt. % to 5 wt. % relative to the monomer or the monomer mixture, preferably in amounts from 0.1 wt. % to 2 wt. % and especially preferably in amounts from 0.2 wt. % to 1 wt. %, relative to the monomer or monomer mixture (cf. for example H. Rauch-Puntigam, Th. Völker, “Acrylic and methacrylic compounds”, Springer, Heidelberg, 1967; Houben-Weyl, Methoden der organischen Chemie [Methods of organic chemistry], Vol. XIV/1, page 66, Georg Thieme, Heidelberg, 1961 or Kirk-Othmer, Encyclopedia of Chemical Technology, Vol. 1, pages 296ff, J. Wiley, New York, 1978). Especially preferably, n-dodecylmercaptan is used as molecular-weight regulator.

Within the scope of the present invention, furthermore at least one compound according to formula (I)

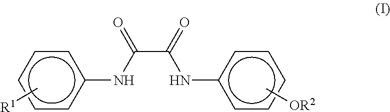

in which the residues R¹ and R² represent independently an alkyl or cycloalkyl residue with 1 to 20 carbon atoms, especially preferably with 1 to 8 carbon atoms, is used for production of the solar cell modules. The aliphatic residues are preferably linear or branched and can have substituents, for example halogen atoms.

The preferred alkyl groups include the methyl, ethyl, propyl, isopropyl, 1-butyl, 2-butyl, 2-methylpropyl, tert.-butyl, pentyl, 2-methylbutyl, 1,1-dimethylpropyl, hexyl, heptyl, octyl, 1,1,3,3-tetramethylbutyl, nonyl, 1-decyl, 2-decyl, undecyl, dodecyl, pentadecyl and the eicosyl group.

The preferred cycloalkyl groups include the cyclopropyl, cyclobutyl, cyclopentyl, cyclohexyl, cycloheptyl and the cyclooctyl group, which are optionally substituted with branched or unbranched alkyl groups.

Especially preferably the compound of formula (II)

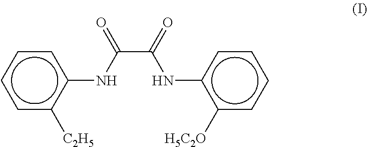

is used.

This compound is available commercially from Clariant under the trade name ®Sanduvor VSU and from Ciba Geigy under the trade name ®Tinuvin 312.

Within the scope of the present invention it may optionally be useful in addition to use additives that are well known by a person skilled in the art. External lubricants, antioxidants, flame retardants, additional UV stabilizers, preferably HALS stabilizers, flow improvers, metal additives for screening against electromagnetic radiation, antistatic agents, mould-release agents, dyes, pigments, adhesion promoters, antiweathering agents, plasticizers, fillers and the like are preferred.

Within the scope of an especially preferred embodiment of the present invention, at least one sterically hindered amine is used, giving a further improvement in resistance to weathering. Yellowing or degradation of materials exposed to external conditions for a long time can be further reduced.

Especially preferred sterically hindered amines include dimethylsuccinate-1-(2-hydroxyethyl)-4-hydroxy-2,2,6,6-tetramethylpiperazine polycondensate, poly[{6-(1,1,3,3-tetramethylbutyl)amino-1,3,5-triazine-2,4-diyl}{(2,2,6,6-tetramethyl-4-piperidyl)imino}hexamethylene{(2,2,6,6-tetramethyl-4-piperidyl)imino}], N,N′-bis(3-aminopropyl)ethylenediamine-2,4-bis[N-butyl-N-(1,2,2,6,6-pentamethyl-4-piperidyl)amino]-6-chloro-1,3,5-triazine condensate, bis(2,2,6,6-tetramethyl-4-piperidyl)sebacate and 2-(3,5-di-t-4-hydroxybenzyl)-2-n-butylmalonate bis(1,2,2,6,6-pentamethyl-4-piperidyl).

Furthermore, the use of silane adhesion promoters or organic titanium compounds has proved quite especially useful, giving further improvement in adhesion to inorganic materials.

Suitable silane adhesion promoters include vinyltrichlorosilane, vinyl-tris(β-methoxyethoxy)silane, vinyltriethoxysilane, vinyltrimethoxysilane, γ-methacryloxypropyltrimethoxysilane, β-(3,4-epoxycyclohexyl)ethyltrimethoxysilane, γ-glycidoxypropylmethyldiethoxysilane, N-β-(aminoethyl)-γ-aminopropyltrimethoxysilane, N-β-(aminoethyl)-γ-aminopropylmethyldimethoxysilane, γ-aminopropyltriethoxysilane, N-phenyl-γ-aminopropyltrimethoxysilane, γ-mercaptopropyltrimethoxysilane and γ-chloropropyltrimethoxysilane.

The relative proportions of the polyalkyl(meth)acrylate and the compound according to formula (I) can in principle be selected freely.

In a first preferred embodiment the components a) and b) are present in a common moulding compound. Especially preferred moulding compounds comprise, in each case relative to their total weight, 90 wt. % to 99.999 wt. % of polyalkyl(meth)acrylate, where the concentration of the compound according to formula (I) is in the aforementioned range or preferred range.

The compounds can be incorporated in a common moulding compound by methods that are known from the literature, for example by mixing with the polymer prior to further processing at higher temperature, by addition to the polymer melt or by addition to the suspended or dissolved polymer while it is being processed. They can optionally also already be added to the starting materials for production of the polymer, and they do not lose their absorption capacity even in the presence of other usual light and heat stabilizers, oxidizing and reducing agents and the like.

A moulding compound that is especially preferred for the purposes of the present invention has a softening temperature of not less than 80° C. (Vicat softening temperature VST (ISO 306-B50)). It is therefore particularly suitable as a reinforcing agent for solar cell modules, as it does not begin to creep, even if the module is exposed to high temperatures during use.

In a second preferred embodiment, the monomers polymerizable to components a) and the UV absorber b) are optionally mixed with other aforementioned components to a polymerizable monomer mixture (casting monomer mixture). Casting monomer mixtures comprise, within the scope of the present invention, both mixtures of monomers and mixtures of monomers, polymers and oligomers, so-called syrup or resin mixtures. Solar cell elements can be produced from the casting monomer mixtures by known methods, preferably chamber polymerization and continuous casting polymerization.

Especially advantageous solar cell elements are those produced from moulding compounds and/or casting monomer mixtures that possess relatively high total transparency and in this way, especially when used as reinforcing agent in solar cell modules, especially in multijunction solar cells, prevent a drop in performance of the solar cell, which could be caused by optical loss of the reinforcing agent. Over the wavelength range from 400 nm to less than 500 nm the total transparency is preferably at least 90%. Over the wavelength range from 500 nm to less than 1000 nm the total transparency is preferably at least 80% (measurement using the Lambda 19 spectrophotometer from the company Perkin Elmer).

Moreover, solar cell elements from moulding compounds and/or casting monomer mixtures are also advantageous that have a leakage resistance of 1-500 kΩ×cm². There is optimum avoidance of a drop in performance of the solar cell due to short circuits.

Solar cell elements from moulding compounds and/or casting monomer mixtures that contain the stated constituents are suitable in particular as reinforcing agent for solar cell modules, in particular in the case of multijunction solar cells. Furthermore, they are preferably used for the production of so-called light concentrators. These are components that concentrate light extremely efficiently on an area that is as small as possible, and thus achieve a high intensity of irradiation. It is not necessary, in this case, to produce an image of the light source.

Light concentrators that are especially advantageous for the purposes of the present invention are converging lenses, which collect parallel incident light and concentrate it on the focal plane. In particular, incident light parallel to the optical axis is brought to the focus.

Converging lenses can be biconvex (bulging outwards on both sides), planoconvex (1 side flat, 1 side convex) or concavoconvex (1 side curved inward, 1 side curved outward, the convex side preferably more curved than the concave side). Converging lenses that are especially preferred according to the invention comprise at least one convex region, and planoconvex structures have been found to be quite especially advantageous.

Within the scope of an especially preferred embodiment of the present invention, the light concentrators have the structure of a Fresnel lens. This is an optical lens which, because of the design employed, generally leads to a reduction in weight and volume, which is especially effective for large lenses with short focal length.

The decrease in volume with a Fresnel lens is achieved by dividing it into annular regions. In each of these regions the thickness is reduced, so that the lens has a series of annular steps. As light is only refracted on the surface of the lens, the angle of refraction does not depend on the thickness, but only on the angle between the two surfaces of a lens. Therefore the lens retains its focal length, although the picture quality is impaired by the stepped structure.

Within the scope of a first especially preferred embodiment of the present invention, lenses with rotational symmetry and with a Fresnel structure towards the optical axis are used. They focus the light in one direction onto a point.

Within the scope of another especially preferred embodiment of the present invention, linear lenses with a Fresnel structure are used, which focus the light in one plane.

Otherwise, the solar cell module can have a structure that is known per se. It preferably comprises at least one photovoltaic cell, which advantageously is inserted and laminated between a plate and a rear wall, the plate and the rear wall advantageously being secured in each case with a reinforcing agent on the photovoltaic cell. The solar cell module, in particular the plate, the rear wall and/or the reinforcing agent, preferably comprise the components used according to the invention, i.e. polyalkyl(meth)acrylate and the compound according to formula (I).

Within the scope of another quite especially preferred embodiment of the present invention, the solar cell module comprises
a) at least one photovoltaic cell,
b) at least one light concentrator, which contains at least one polyalkyl(meth)acrylate, and
c) at least one transparent plate, which contains at least one compound according to formula (I),
   wherein the solar cell module has at least one component comprising a polyalkyl(meth)acrylate and the concentration of the compound according to formula (I) in this component/these components is in the range defined below

$${C}_{UV - absorber} = \frac{0.1 [ wt . \% \times mm ]}{{d}_{moulding} [ mm ]} to \frac{0.6 [ wt . \% \times mm ]}{{d}_{moulding} [ mm ]} .$$

An especially advantageous structure of a solar cell module is described hereunder, referring from time to time to the diagrams in FIG. 1 to FIG. 2B.

The solar cell module according to the invention preferably comprises a photovoltaic cell 101, a plate 103, which covers the front of the photovoltaic cell 101, a first reinforcing agent 102 between the photovoltaic cell 101 and the plate 103, a rear wall 105, which covers the back 104 of the photovoltaic cell 101 and a second reinforcing agent 104 between the photovoltaic cell 101 and the rear wall 105.

The photovoltaic cell preferably comprises a photoactive semiconductor layer on a conductive substrate as a first electrode for conversion of light and a transparent conductive layer as a second electrode, which is formed on top of it.

In this connection, the conductive substrate preferably comprises stainless steel, by which the strength of adhesion of the reinforcing agent on the substrate is further improved.

A collector electrode, which contains copper and/or silver as a constituent, is preferably formed on the light-sensitive side of the photovoltaic cell and an element containing polyalkyl(meth)acrylate, which preferably contains at least one compound according to formula (I) at the aforementioned concentration, is preferably brought in contact with the collector electrode.

The light-sensitive surface of the photovoltaic cell is advantageously covered with an element that contains a polyalkyl(meth)acrylate, which has at least one compound according to formula (I) at the aforementioned concentration, and then preferably a thin fluoride polymer film is arranged thereon as the outermost layer.

The first reinforcing agent 102 should protect the photovoltaic cell 101 against external factors, by covering any unevenness of the light-sensitive surface of the cell 101. It also serves for bonding the plate 103 to the cell 101. Therefore it should have high resistance to weathering, good adhesion and high heat resistance, in addition to high transparency. Furthermore, it should have low water absorption and should not release any acid. In order to satisfy these requirements, preferably a polyalkyl(meth)acrylate is used as the first reinforcing agent, which preferably contains at least one compound according to formula (I) at the aforementioned concentration.

In order to minimize any reduction of the amount of light reaching the photovoltaic cell 101, the transparency of the first reinforcing agent 102 in the visible wavelength range from 400 nm to 800 nm is preferably at least 80%, especially preferably at least 90% in the wavelength range from 400 nm to less than 500 nm (measurement using the Lambda 19 spectrophotometer from the company Perkin Elmer). Furthermore, it preferably has a refractive index of 1.1-2.0, advantageously of 1.1-1.6, to facilitate incidence of light from air (measurement according to ISO 489).

The second reinforcing agent 104 is used for protecting the photovoltaic cell 101 against external factors, by covering any unevenness on the back of the cell 101. Furthermore, it also serves for bonding the rear wall 105 to the cell 101. Therefore the second reinforcing agent should, like the first reinforcing agent, have high resistance to weathering, good adhesion and high heat resistance. It is therefore also preferable to use a polyalkyl(meth)acrylate, which preferably contains at least one compound according to formula (I), as the second reinforcing agent. Preferably the same material is used both for the first reinforcing agent and for the second reinforcing agent. However, since transparency is optional, a filler, such as an organic oxide, can if required be added to the second reinforcing agent, for further improving the resistance to weathering and the mechanical properties, or a pigment can be added in order to colour it.

Preferably, known cells are used as the photovoltaic cell 101, in particular monocrystalline silicon cells, polycrystalline silicon cells, amorphous silicon and microcrystalline silicon, such as are also used in thin film silicon cells. Furthermore, copper-indium selenide and semiconductor compounds are also especially suitable.

A schematic block diagram of a preferred photovoltaic cell is shown in FIGS. 2a and 2b. FIG. 2a is a schematic sectional view of a photovoltaic cell, whereas FIG. 2b is a schematic top view of a photovoltaic cell. In these diagrams the number 201 denotes a conductive substrate, 202 a reflective layer on the back, 203 a photoactive semiconductor layer, 204 a transparent, conductive layer, 205 a collector electrode, 206a and 206b connectors and 207 and 208 conductive, adhesive or conductive pastes.

The conductive substrate 201 serves not only as the substrate of the photovoltaic cell, but also as the second electrode. The material of the conductive substrate 201 preferably comprises silicon, tantalum, molybdenum, tungsten, stainless steel, aluminium, copper, titanium, a carbon film, a lead-coated steel plate, a resin film and/or ceramic with a conductive layer on it.

On the conductive substrate 201, preferably a metal layer, a metal oxide layer or both are provided as reflective layer 202 on the back. The metal layer preferably comprises Ti, Cr, Mo, B, Al, Ag and/or Ni, whereas the metal oxide layer preferably contains ZnO, TiO₂ and SnO₂. The metal layer and the metal oxide layer are formed advantageously by chemical vapour deposition by heating or by electron beam or by sputtering.

The photoactive semiconductor layer 203 serves for carrying out the photoelectric conversion. Preferred materials in this connection are polycrystalline silicon with pn junction, PIN junction types from amorphous silicon, PIN junction types from microcrystalline silicon and semiconductor compounds, in particular CuInSe₂, CuInS₂, GaAs, CdS/Cu₂S, CdS/CdTe, CdS/InP and CdTe/Cu₂Te. The use of PIN junction types from amorphous silicon is especially preferred.

The photoactive semiconductor layer is preferably produced by forming molten silicon into a film, or by heat treatment of amorphous silicon in the case of polycrystalline silicon, by plasma chemical vapour deposition using a silane gas as starting material in the case of amorphous silicon and microcrystalline silicon and by ion plating, ion beam deposition, vacuum evaporation, sputtering or galvanizing in the case of a semiconductor compound.

The transparent conductive layer 204 serves as the upper electrode of the solar cell. It preferably comprises In₂O₃, SnO₂, In₂O₃—SnO₂ (ITO), ZnO, TiO₂, Cd₂SnO₄ or a crystalline semiconductor layer, which is doped with a high concentration of impurities. It can be formed by resistance-heating vapour deposition, sputtering, spraying, chemical vapour deposition or by diffusion of impurities.

Moreover, in the case of the photovoltaic cell on which the transparent conductive layer 204 was formed, the conductive substrate and the transparent, conductive layer may partially be short-circuited owing to the unevenness of the surface of the conductive substrate 201 and/or the non-uniformity at the moment of formation of the photoactive semiconductor layer. In this case there is a large current loss that is proportional to the output voltage. That is, the leakage resistance (shunt resistance) is low. Therefore it is desirable to remove short circuits and, after formation of the transparent conductive layer, submit the photovoltaic cell to a treatment for removing defects. Such a treatment is described in detail in U.S. Pat. No. 4,729,970. As a result of this treatment, the shunt resistance of the photovoltaic cell is adjusted to 1-500 kΩ×cm², preferably to 10-500 kΩ×cm².

The collector electrode (grid) can be formed on the transparent conductive layer 204. Preferably it has the form of a grid, a comb, a line or similar, for efficiently collecting the electric current. Preferred examples of the material forming the collector electrode 205 are Ti, Cr, Mo, W, Al, Ag, Ni, Cu, Sn or a conductive paste, which is called silver paste.

The collector electrode 205 is preferably formed by sputtering using a mask, by resistance heating, by chemical vapour deposition, by a method comprising the steps in which a metal film is formed over the whole layer by vapour deposition and the parts of the film not required are removed by etching, by a method in which a grid electrode pattern is formed by photochemical vapour deposition, by a method comprising the steps in which a negative mask of the grid electrode is formed and the pattern surface is plated, by a method in which a conductive paste is printed, by a method in which metal wires are soldered onto a printed conductive paste. The conductive paste used is preferably a polymer binder, in which silver, gold, copper, nickel, carbon or similar is dispersed in the form of a fine powder. The polymer binder preferably includes polyester resins, ethoxy resins, acrylic resins, alkyd resins, polyvinyl acetate resins, rubbers, urethane resins and/or phenolic resins.

Finally, preferably tapping terminals 206 are fastened on the conductive substrate 201 or on the collector electrode 205, for tapping the electromotive force. The tapping terminals 206 are fastened on the conductive substrate preferably by fastening a metal body, e.g. a copper lug, on the conductive substrate by spot welding or soldering, whereas fastening of the tapping terminals on the collector electrode is preferably effected by connecting a metal body electrically to the collector electrode with a conductive paste or with tin solder 207 and 208.

The photovoltaic cells are connected either in series or in parallel, depending on the required voltage or current. Furthermore, the voltage or current can be controlled by inserting the photovoltaic cells into an insulating substrate.

The plate 103 in FIG. 1 should possess maximum possible resistance to weathering, optimum dirt-repellent action and the highest possible mechanical strength, as it is the outermost layer of the solar cell module. Furthermore, it must ensure long-term reliability of the solar cell module in outdoor use. Plates that are suitable for use for the purposes of the present invention include (reinforced) glass films and fluoride polymer films. The glass film used is preferably a glass film with high transparency. Suitable fluoride polymer films comprise in particular ethylene tetrafluoride-ethylene copolymer (ETFE), polyvinyl fluoride resin (PVF), polyvinylidene fluoride resin (PVDF), tetrafluoroethylene resin (TFE), ethylene tetrafluoride-propylene hexafluoride copolymer (FEP) and chlorotrifluoroethylene (CTFE). Polyvinylidene fluoride resin is especially suitable with respect to resistance to weathering, whereas ethylene tetrafluoride-ethylene copolymer is especially advantageous with respect to the combination of resistance to weathering and mechanical strength. To improve adhesion between the fluoride polymer film and the reinforcing agent, it is desirable for the film to undergo a corona treatment or a plasma treatment. Furthermore, the use of stretched films is also preferred, for further improvement in mechanical strength.

Within the scope of an especially preferred embodiment of the present invention, the plate comprises at least one polyalkyl(meth)acrylate and preferably in addition at least one compound according to formula (I) at the aforementioned concentration.

The plate is, furthermore, preferably a light concentrator, which concentrates light very efficiently on the photovoltaic cell, thus achieving a high intensity of irradiation. Converging lenses, which collect parallel incident light and focus it in the focal plane, are especially preferred. In particular, incident light parallel to the optical axis is focused at the focal point.

Converging lenses can be biconvex, planoconvex or concavoconvex. However, planoconvex structures are especially preferred. Furthermore, the plate preferably has the structure of a Fresnel lens.

The rear wall 105 serves for electrical insulation between the photovoltaic cell 101 and the surroundings and for improving resistance to weathering and acts as a reinforcing material. It is preferably formed from a material that ensures adequate electrically insulating properties, has excellent long-term durability, can withstand thermal expansion and thermal contraction, and is flexible. Materials that are especially suitable for these purposes include nylon films, polyethylene terephthalate (PET) films and polyvinyl fluoride films. If moisture resistance is required, it is preferable to use aluminium-laminated polyvinyl fluoride films, aluminium-coated PET films, silicon oxide-coated PET films. Furthermore, the fire resistance of the module can be improved by using film-laminated, galvanized iron foil or stainless steel foil as the rear wall.

Within the scope of an especially preferred embodiment of the present invention, the rear wall comprises at least one polyalkyl(meth)acrylate, which in addition preferably contains at least one compound according to formula (I).

A supporting plate can be fastened on the outside surface of the rear wall, for further improving the mechanical strength of the solar cell module or to prevent bulging and sagging of the rear wall as a result of temperature changes. Especially preferred rear walls are sheets of stainless steel, plastic sheets and sheets of FRP (fibre-reinforced plastic). Furthermore, a building material can be fastened on the back plate.

A solar cell module of this kind can be produced in a manner that is known per se. However, a procedure that is described hereunder is especially advantageous.

For covering the photovoltaic cell with the reinforcing agent, preferably a method is used in which the reinforcing agent is melted thermally and is extruded through a slot, to form a film, which is then fastened thermally on the cell. The film of reinforcing agent is preferably inserted between the cell and the plate and between the cell and the rear wall, and then cured.

Thermal fastening can be carried out using known methods, e.g. vacuum lamination and roll lamination.

The solar cell module according to the invention preferably has an operating temperature of up to 80° C. or higher, and especially at high temperatures, the heat-resistant effect of the materials according to the invention can be utilized effectively.

The following examples serve for more detailed explanation and better understanding of the present invention, but do not restrict it in any respect.

### EXAMPLES

The following moulding compounds were prepared and the transmission spectrum of the mouldings produced from them with a thickness of 3 mm was measured (for spectra see appendix):

Comparative example 1: PLEXIGLAS® 7H from the company Evonik® Röhm GmbH
Comparative example 2: PLEXIGLAS® 7H with 0.1 wt. % Tinuvin® P (benzotriazole-based UV absorber)
Example 1: PLEXIGLAS® 7H with 0.04 wt. % Tinuvin® 312
Example 2: PLEXIGLAS® 7H with 0.06 wt. % Tinuvin® 312
Example 3: PLEXIGLAS® 7H with 0.08 wt. % Tinuvin® 312
Example 4: PLEXIGLAS® 7H with 0.1 wt. % Tinuvin® 312
Example 5: PLEXIGLAS® 7H with 0.2 wt. % Tinuvin®312
Example 6: PLEXIGLAS® 7H with 0.04 wt. % Tinuvin® 312 and 0.04 wt. % Tinuvin® 770

The transmission spectrum of the sample of Plexiglass® 7H (comparative example 1) in FIG. 4 shows that a high proportion of the UV light passes through the sample and thus also contributes to the heating of the corresponding solar module. However, it is only at certain wavelengths that light is converted to energy by corresponding solar-conversion cells. This wavelength range begins as a rule in the near UV region (starting from 350 nm) and ends—depending on the conversion cell used—in the (near) IR region.

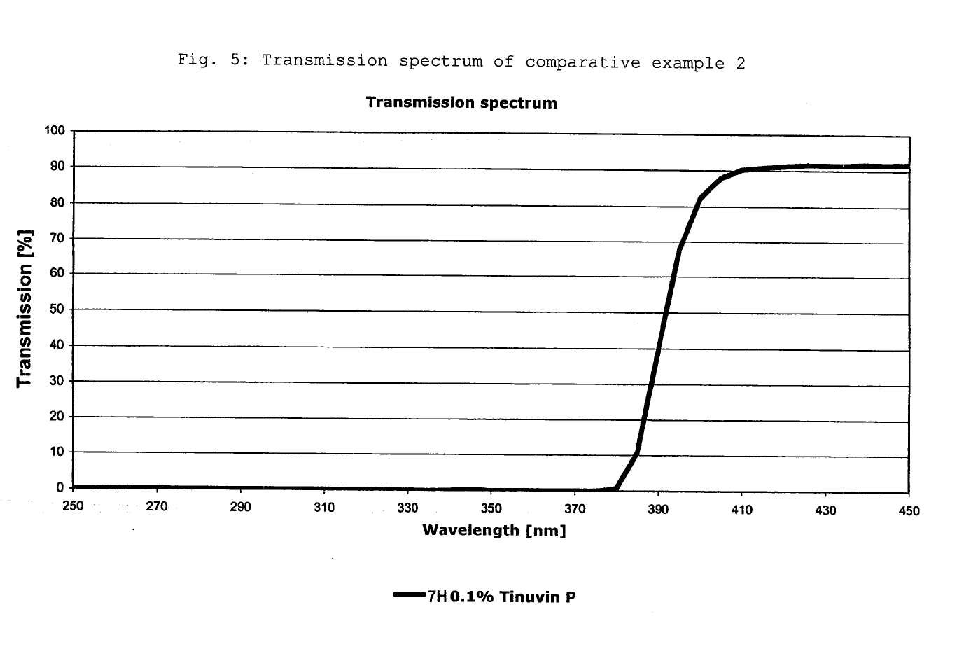

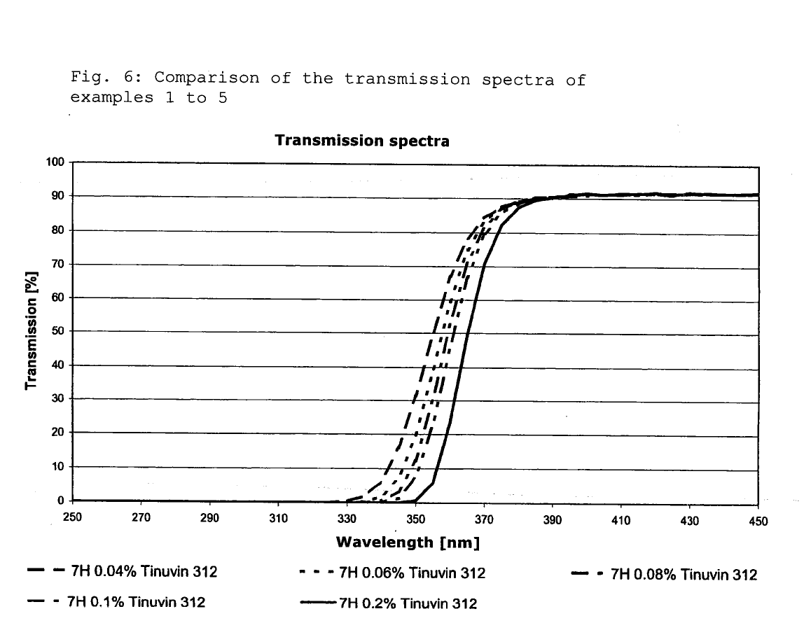

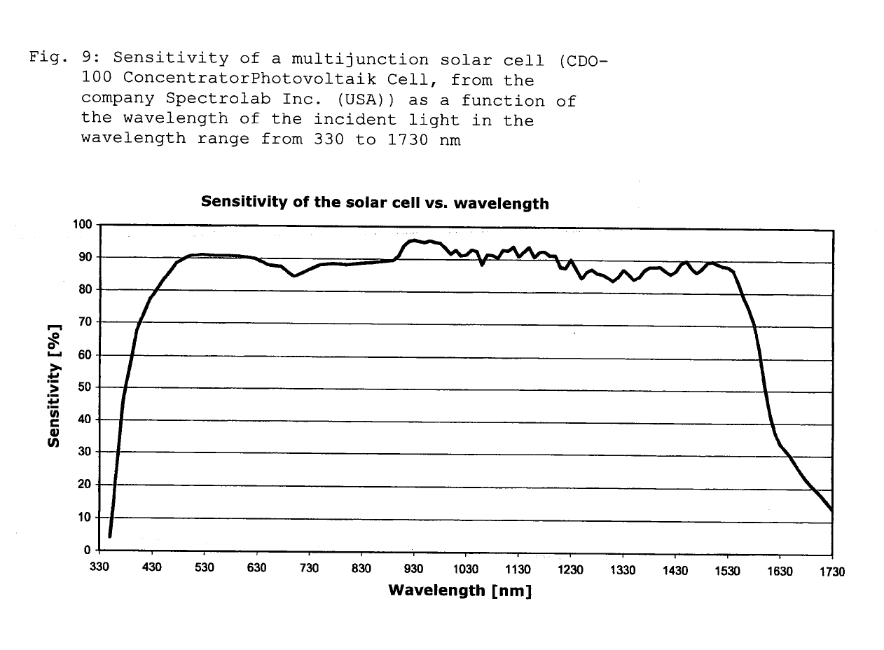

On comparing the transmission spectra, it can be seen that in examples 1 to 6 (see FIG. 6) a much higher proportion of UV light passes through the corresponding plates, than in comparative example 2 (see FIG. 5). This is of advantage if the conversion cell used is a multiple cell, the sensitivity of which can be seen from the wavelength in FIGS. 8 and 9.

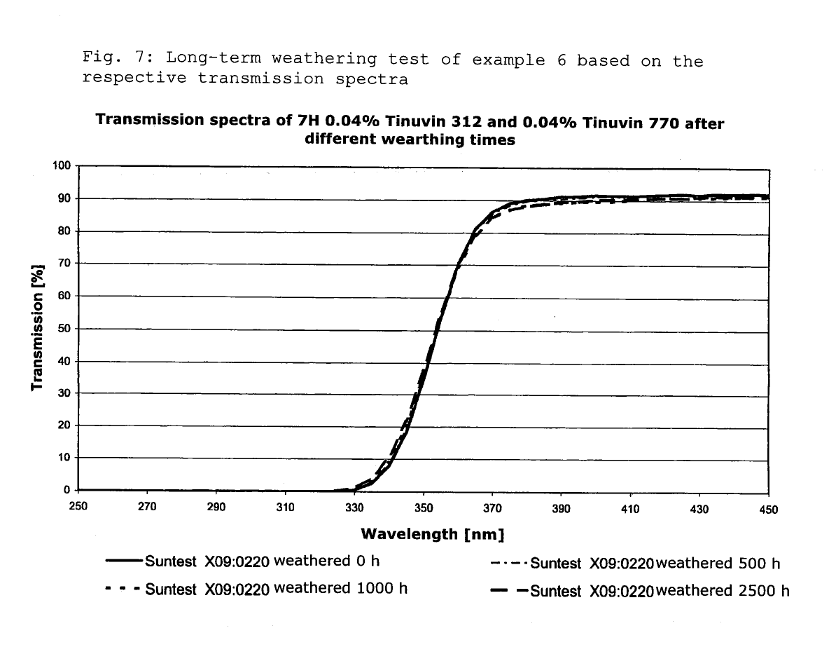

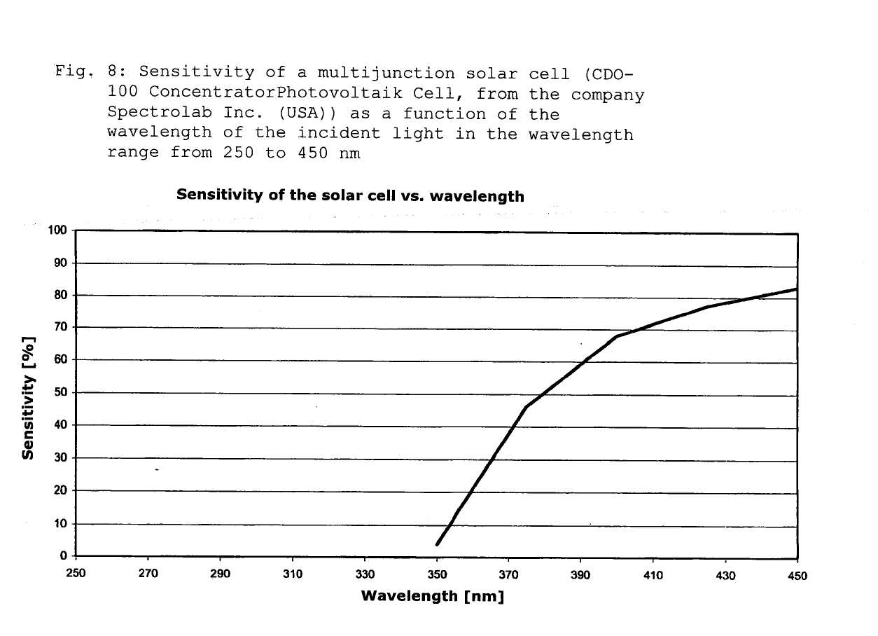

Moreover, it can be shown that the transmission spectrum is largely preserved after at least 2500 h of Suntest weathering, if the moulding compound with addition of TINUVIN® 312 is additionally stabilized with TINUVIN® 770 (a HALS stabilizer, bis(2,2,6,6-tetramethyl-4-piperidinyl)sebacate) (see FIG. 7). The Suntest is a method of assessing the weathering resistance of samples based on the standard DIN EN ISO 4892-2. As a departure from the standard, the tests shown in the FIG. 7 were carried out without a drizzle cycle. That is, the samples are irradiated with a constant 60 W/m². The item “relative humidity at 65+/−10%” of the standard is omitted.

1. A process for producing a solar cell module, the process comprising:
combining
a) a (poly)alkyl(meth)acrylate and
b) a compound of formula (I): 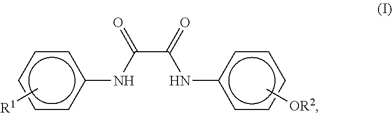
wherein R¹ and R² are each independently an alkyl or cycloalkyl residue comprising 1 to 20 carbon atoms,
with a solar cell, such that a concentration of the compound of formula (I) in a component comprising the polyalkyl(meth)acrylate is in a range defined below
$${C}_{UV - absorber} = \frac{0.1 [ wt . \% \times mm ]}{{d}_{moulding} [ mm ]} to \frac{0.6 [ wt . \% \times mm ]}{{d}_{moulding} [ mm ]} .$$

2. The process of claim 1, wherein the components a) and b), optionally together with further components, are processed in a casting process to a solar module or to a component of a solar module or to a molding compound.

3. The process of claim 1, wherein component a) and component b) are comprised in a molding compound or a casting monomer mixture and the molding compound or the casting monomer mixture comprises, as component a), a C₁-C₁₈ alkyl(meth)acrylate homopolymer or copolymer.

4. The process of claim 1, wherein the molding compound or the casting monomer mixture comprises, as component a), a copolymer, comprising 80 wt. % to 99 wt. % of methyl methacrylate units and 1 wt. % to 20 wt. % of C₁-C₁₀ alkyl acrylate units.

5. The process of claim 1, wherein, in formula (I), R¹ and R² are each independently an alkyl or cycloalkyl residue comprising 1 to 8 carbon atoms, which are optionally substituted with branched or unbranched alkyl groups.

6. The process of claim 1, wherein the compound of formula (I) has formula (II).

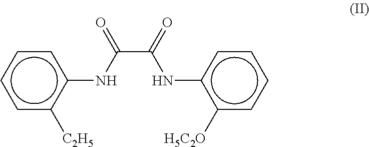

7. The process of claim 1, wherein a concentration of the compound formula (I), in the polyalkyl(meth)acrylate-comprising component is in the range defined below
$${C}_{UV - absorber} = \frac{0.15 [ wt . \% \times mm ]}{{d}_{moulding} [ mm ]} to \frac{0.45 [ wt . \% \times mm ]}{{d}_{moulding} [ mm ]}$$

8. A solar cell module, comprising a molding comprising
a) a polyalkyl(meth)acrylate; and
b) a compound according to of formula (I): 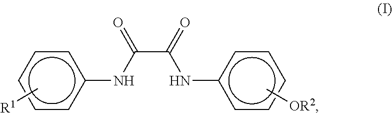
wherein R¹ and R² are each independently an alkyl or cycloalkyl residue comprising 1 to 20 carbon atoms,
wherein the solar cell comprises a component comprising the polyalkyl(meth)acrylate and the compound of formula (I), and wherein a concentration of the compound of formula (I) in the component is in a range defined below
$${C}_{UV - absorber} = \frac{0.1 [ wt . \% \times mm ]}{{d}_{moulding} [ mm ]} to \frac{0.6 [ wt . \% \times mm ]}{{d}_{moulding} [ mm ]} .$$

9. The solar cell module of claim 8, wherein the molding is a light concentrator.

10. The solar cell module of claim 9, wherein the molding is a converging lens.

11. The solar cell module of claim 10, wherein the converging lens comprises a convex region.

12. The solar cell module of claim 11, wherein the converging lens has a planoconvex structure.

13. The solar cell module of claim 12, wherein the converging lens is a Fresnel lens.

14. The solar cell module of claim 9, further comprising a photovoltaic cell.

15. A solar cell module, comprising:
a) a photovoltaic cell,
b) a converging lens comprising a polyalkyl(meth)acrylate, and
c) a transparent plate, a compound of formula (I): 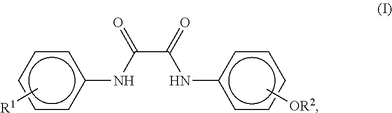
wherein R¹ and R² are each independently an alkyl or cycloalkyl residue comprising 1 to 20 carbon atoms,
wherein the solar cell module comprises a component comprising the polyalkyl(meth)acrylate and the compound of formula (I), and wherein a concentration of the compound of formula (I) in the component is in a range defined below
$${C}_{UV - absorber} = \frac{0.1 [ wt . \% \times mm ]}{{d}_{moulding} [ mm ]} to \frac{0.6 [ wt . \% \times mm ]}{{d}_{moulding} [ mm ]} .$$

16. The process of claim 5, wherein, in formula (I), R¹ and R² are each independently an alkyl or cycloalkyl residue selected from the group consisting of a methyl, ethyl, propyl, isopropyl, 1-butyl, 2-butyl, 2-methylpropyl, tert.-butyl, pentyl, 2-methylbutyl, 1,1-dimethylpropyl, hexyl, heptyl, octyl, 1,1,3,3-tetramethylbutyl, nonyl, 1-decyl, 2-decyl, undecyl, dodecyl, pentadecyl, eicosyl, cyclopropyl, cyclobutyl, cyclopentyl, cyclohexyl, cycloheptyl, and cyclooctyl group, which are optionally substituted with branched or unbranched alkyl groups.

17. The process of claim 6, wherein a concentration of the compound formula (II), in the polyalkyl(meth)acrylate-comprising component is in the range defined below
$${C}_{UV - absorber} = \frac{0.15 [ wt . \% \times mm ]}{{d}_{moulding} [ mm ]} to \frac{0.45 [ wt . \% \times mm ]}{{d}_{moulding} [ mm ]} .$$

18. The process of claim 6, wherein a concentration of the compound formula (II), in the polyalkyl(meth)acrylate-comprising component is in the range defined below
$${C}_{UV - absorber} = \frac{0.15 [ wt . \% \times mm ]}{{d}_{moulding} [ mm ]} to \frac{0.4 [ wt . \% \times mm ]}{{d}_{moulding} [ mm ]} .$$

19. The process of claim 6, wherein a concentration of the compound formula (II), in the polyalkyl(meth)acrylate-comprising component is in the range defined below
$${C}_{UV - absorber} = \frac{0.15 [ wt . \% \times mm ]}{{d}_{moulding} [ mm ]} to \frac{0.3 [ wt . \% \times mm ]}{{d}_{moulding} [ mm ]} .$$
